(19) United States
(12) Patent Application Publication
(10) Pub. No.: US 2005/0077530 A1
(43) Pub. Date: Apr. 14, 2005

(54) Gallium nitride (GaN)-based semiconductor light emitting diode and method for manufacturing the same

(76) Inventor: Seung Wan Chae, Yongin (KR)

Correspondence Address: LOWE HAUPTMAN GILMAN & BERNER, LLP, Suite 310, 1700 Diagonal Road, Alexandria, VA, 22314, US

(21) Appl. No.: 10/812,015

(22) Filed: Mar. 30, 2004

(30) Foreign Application Priority Data
Oct. 10, 2003 (KR) 2003-70608

(51) Int. Cl. H01L 33/00

(52) U.S. Cl. 257/94

(57) ABSTRACT

Disclosed are a GaN-based semiconductor light emitting diode, in which transmittance of electrodes is improved and high-quality Ohmic contact is formed, and a method for manufacturing the same, thus improving luminance and driving voltage properties. The GaN-based semiconductor light emitting diode includes: a substrate on which a GaN-based semiconductor material is grown; a lower clad layer formed on the substrate, and made of a first conductive GaN semiconductor material; an active layer formed on a designated portion of the lower clad layer, and made of an undoped GaN semiconductor material; an upper clad layer formed on the active layer, and made of a second conductive GaN semiconductor material; and an alloy layer formed on the upper clad layer, and made of a hydrogen-storing alloy. The GaN-based semiconductor light emitting diode improves a luminance property and reduces Ohmic resistance, thus obtaining high-quality Ohmic contact.

### BACKGROUND OF THE INVENTION

1. Field of the Invention

The present invention relates to a GaN-based semiconductor light emitting diode, and more particularly to a GaN-based semiconductor light emitting diode in which transmittance of electrodes is improved and high-quality Ohmic contact is formed, and a method for manufacturing the GaN-based semiconductor light emitting diode, thus having a good luminance property and being operated at a low driving voltage.

2. Description of the Related Art

Recently, LED displays, serving as visual information transmission media, starting from providing alpha-numerical data have been developed to provide various moving pictures such as CF images, graphics, video images, etc. Further, the LED displays have been developed so that light emitted from the displays is changed from a solid color into colors in a limited range using red and yellowish green LEDs and then into total natural colors using the red and yellowish green LEDs and a newly proposed GaN high-brightness blue LED. However, the yellowish green LED emits a beam having a brightness lower than those of the red and blue LEDs and a wavelength of 565 nm, which is unnecessary for displaying the three primary colors of light. Accordingly, with the yellowish green LED, it is impossible to substantially display the total natural colors. Thereafter, in order to solve the above problems, there has been produced a GaN high-brightness pure green LED, which emits a beam having a wavelength of 525 nm suitable for displaying the total natural colors.

Generally, the above-described GaN-based semiconductor light emitting diode is grown on an insulating sapphire substrate. Accordingly, differing from a GaAs-based semiconductor light emitting diode, an electrode is not formed on a rear surface of the substrate and both electrodes are formed on a front surface of the substrate on which crystals are grown. FIG. 1 illustrates a structure of the above conventional GaN-based light emitting diode.

With reference to FIG. 1, a GaN-based light emitting diode 20 comprises a sapphire substrate 11, a lower clad layer 13 made of a first conductive semiconductor material, an active layer 14, and a second clad layer 15 made of a second conductive semiconductor material. Here, the first clad layer 13, the active layer 14 and the second clad layer 15 are sequentially formed on the sapphire substrate 11.

The lower clad layer 13 includes an n-type GaN layer 13a and an n-type AlGaN layer 13b. The active layer 14 includes an undoped InGaN layer having a multi-quantum well structure. The upper clad layer 15 includes a p-type GaN layer 15a and a p-type AlGaN layer 15b. Generally, semiconductor crystalline layers, i.e., the lower clad layer 13, the active layer 14 and the upper clad layer 15, are grown on the sapphire substrate 11 using a process such as the MOCVD (Metal Organic Chemical Vapor Deposition) method. In order to improve lattice matching of the n-type GaN layer 13a with the sapphire substrate 11, an AlN/GaN buffer layer (not shown) may be formed on the sapphire substrate 11 prior to the growth of the n-type GaN layer 13a thereon.

As described above, in order to form both electrodes on an upper surface of the electrically insulating sapphire substrate 11, designated portions of the upper clad layer 15 and the active layer 14 are removed by etching, thereby selectively exposing the lower clad layer 13, more specifically, the n-type GaN layer 13a, to the outside, and allowing a first electrode 21 to be formed on the exposed portion of the n-type GaN layer 13a.

The p-type GaN layer 15a has a comparatively high resistance, and requires an additional layer for forming Ohmic contact serving as conventional electrodes. U.S. patent Ser. No. 5,563,422 (Applicant; Nichia Chemical Industries, Ltd., and Issue Date; Oct. 8, 1006) discloses a method for forming a transparent electrode 18 made of Ni/Au for forming Ohmic contact prior to the formation of a second electrode 22 on the p-type GaN layer 15a. The transparent electrode 18 increases a current injection area and forms Ohmic contact, thus reducing forward voltage (V_{f}). Although the transparent electrode 18 made of Ni/Au is thermally treated, the transparent electrode 18 has a low transmittance of approximately 60% to 70%. The low transmittance of the transparent electrode 18 decreases overall light emitting efficiency of a package of the light emitting diode obtained by a wire-bonding method.

In order to solve the above low transmittance problem, there has been proposed an ITO (Indium Tin Oxide) layer having a transmittance of approximately 90% or more as a substitute for the Ni/Au layer. Since ITO has a weak adhesive force with GaN crystals and a work function of 4.7˜5.2 eV while the p-type GaN has a work function of 7.5 eV, in case that the ITO layer is directly deposited on the p-type GaN layer, Ohmic contact is not formed. Accordingly, in order to form Ohmic contact by reducing a difference of the work functions between the ITO layer and the p-type GaN layer, the conventional p-type GaN layer is doped with a material having a low work function such as Zn, or is high-density doped with C, thus reducing the work function and allowing ITO to be deposited thereon. However, in case that Zn or C having a high mobility is used for a long period of time, Zn or C is diffused into the p-type GaN layer, thus deteriorating reliability of the obtained light emitting diode.

Accordingly, there have been required a GaN-based semiconductor light emitting diode, which maintains a high transmittance in order to form electrodes, and forms high-quality Ohmic contact between a p-type GaN layer and the electrodes, and a method for manufacturing the GaN-based semiconductor light emitting diode.

### SUMMARY OF THE INVENTION

Therefore, the present invention has been made in view of the above problems, and it is an object of the present invention to provide a GaN-based semiconductor light emitting diode, which has a high transmittance and solves problems caused by a contact resistance between a p-type GaN layer and electrodes.

It is another object of the present invention to provide a method for manufacturing the GaN-based semiconductor light emitting diode.

In accordance with one aspect of the present invention, the above and other objects can be accomplished by the provision of a GaN-based semiconductor light emitting diode comprising: a substrate on which a GaN-based semiconductor material is grown; a lower clad layer formed on the substrate, and made of a first conductive GaN semiconductor material; an active layer formed on a designated portion of the lower clad layer, and made of an undoped GaN semiconductor material; an upper clad layer formed on the active layer, and made of a second conductive GaN semiconductor material; and an alloy layer formed on the upper clad layer, and made of a hydrogen-storing alloy.

Preferably, the alloy layer may be made of one hydrogen-storing alloy selected from the group consisting of Mn-based hydrogen-storing alloys, La-based hydrogen-storing alloys, Ni-based hydrogen-storing alloys and Mg-based hydrogen-storing alloys. More preferably, the Mn-based hydrogen-storing alloy may be MnNiFe or MnNi, the La-based hydrogen-storing alloy may be LaNi₅, the Ni-based hydrogen-storing alloy may be ZnNi or MgNi, the Mg-based hydrogen-storing alloy may be ZnMg, and the alloy layer may have a thickness of 10 Å to 100 Å.

Preferably, the GaN-based semiconductor light emitting diode may further comprise a first metal layer formed on the alloy layer and made of one metal selected from the group consisting of Au, Pt, Ir and Ta. More preferably, the first metal layer may have a thickness of 100 Å or less, and the first metal layer may have a thickness the same as or larger than that of the alloy layer.

Further, preferably, the GaN-based semiconductor light emitting diode may further comprise a second metal layer formed on the alloy layer and made of one metal selected from the group consisting of Rh, Al and Ag. More preferably, the second metal layer may have a thickness of 500 Å to 10,000 Å.

In accordance with another aspect of the present invention, there is provided a method for manufacturing a GaN-based semiconductor light emitting diode comprising the steps of: (a) preparing a substrate on which a GaN-based semiconductor material is grown; (b) forming a lower clad layer, made of a first conductive GaN semiconductor material, on the substrate; (c) forming an active layer, made of an undoped GaN semiconductor material, on the lower clad layer; (d) forming an upper clad layer, made of a second conductive GaN semiconductor material, on the active layer; (e) removing designated portions of the upper clad layer and the active layer so as to expose a portion of the lower clad layer; and (f) forming an alloy layer made of a hydrogen-storing alloy on the upper clad layer.

Preferably, the step (f) may be a step of growing the alloy layer on the upper clad layer by a physical vapor evaporation method.

The method may further comprise the step of: (g) allowing the surface of the upper clad layer to undergo UV treatment, plasma treatment or thermal treatment at a temperature of 400° C. or less. Moreover, the method may further comprise the step of: (h) forming a first metal layer, made of one metal selected from the group consisting of Au, Pt, Ir and Ta, on the alloy layer, or (h′) forming a second metal layer, made of one metal selected from the group consisting of Rh, Al and Ag, on the alloy layer.

Preferably, the step (h) may be a step of growing the first metal layer having a thickness of 100 Å or less on the alloy layer by a physical vapor evaporation method, and the first metal layer may have a thickness the same as or larger than that of the alloy layer. Moreover, preferably, the method may further comprise the step of: (I) thermally treating the alloy layer and the first metal layer, and the step (I) may be performed at a temperature of 200° C. or more for 10 seconds or more.

Preferably, the step (h′) may be a step of growing the second metal layer having a thickness of 500 Å to 10,000 Å on the alloy layer by a physical vapor evaporation method. Moreover, preferably, the method may further comprise the step of: (I′) thermally treating the alloy layer and the second metal layer, and the step (I′) may be performed at a temperature of 200° C. or more for 10 seconds or more.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional GaN-based semiconductor light emitting diode;

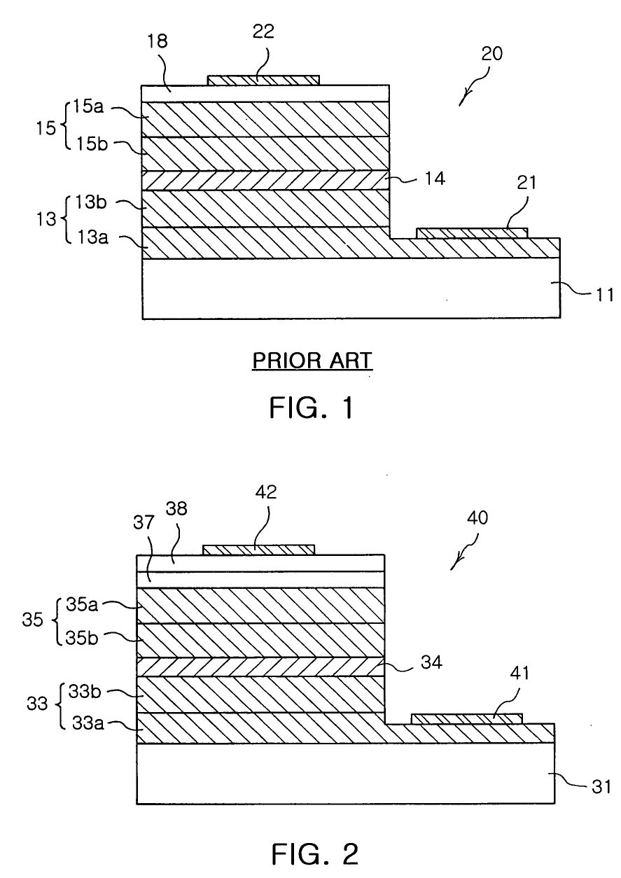

FIG. 2 is a cross-sectional view of a GaN-based semiconductor light emitting diode in accordance with one embodiment of the present invention;

FIG. 3 is a cross-sectional view of a flip chip bonding-type package of the GaN-based semiconductor light emitting diode in accordance with one embodiment of the present invention;

FIGS. 4a to 4d are perspective views illustrating a process for manufacturing a GaN-based semiconductor light emitting diode in accordance with the present invention;

FIGS. 5a to 5c are graphs comparatively illustrating specific contact resistance of a Ni/Au layer of the conventional GaN-based semiconductor light emitting diode and specific contact resistance of an alloy layer/metal layer of the GaN-based semiconductor light emitting diode of the present invention; and

FIGS. 6a and 6b are graphs comparatively illustrating luminance of the conventional GaN-based semiconductor light emitting diode comprising the Ni/Au layer and luminance of the GaN-based semiconductor light emitting diode comprising the alloy layer/metal layer in accordance with the present invention.

### DESCRIPTION OF THE PREFERRED EMBODIMENTS

Now, preferred embodiments of the present invention will be described in detail with reference to the annexed drawings.

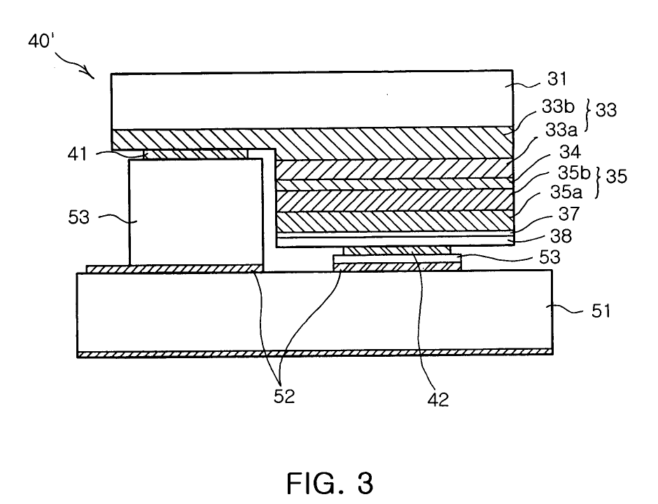

FIG. 2 is a cross-sectional view of a GaN-based semiconductor light emitting diode 40 in accordance with one embodiment of the present invention. With reference to FIG. 2, the GaN-based semiconductor light emitting diode 40 comprises a sapphire substrate 31 on which a GaN base semiconductor material is grown, a lower clad layer 33 made of a first conductive semiconductor material, an active layer 34, a second clad layer 35 made of a second conductive semiconductor material, and an alloy layer 37 made of a hydrogen-storing alloy. Here, the first clad layer 33, the active layer 34, the second clad layer 35 and the alloy layer 37 are sequentially formed on the sapphire substrate 31.

The lower clad layer 33 made of the first conductive semiconductor material includes an n-type GaN layer 33a and an n-type AlGaN layer 33b. The active layer 34 includes an undoped InGaN layer having a multi-quantum well structure. The upper clad layer 35 made of the second conductive semiconductor material includes a p-type GaN layer 35a and a p-type AlGaN layer 35b. Generally, semiconductor crystalline layers, i.e., the lower clad layer 33, the active layer 34 and the upper clad layer 35, are grown on the sapphire substrate 31 using a process such as the MOCVD (Metal Organic Chemical Vapor Deposition) method. In order to improve lattice matching of the n-type GaN layer 33a with the sapphire substrate 31, an AlN/GaN buffer layer (not shown) may be formed on the sapphire substrate 31 prior to the growth of the n-type GaN layer 33a thereon.

Designated portions of the upper clad layer 35 and the active layer 34 are removed, thereby selectively exposing the lower clad layer 33 to the outside. A first electrode 41 is arranged on the exposed portion of the lower clad layer 33, more specifically, the n-type GaN layer 33a in FIG. 2.

A second electrode 42 is formed on a metal layer 38. The p-type GaN layer 35a has a higher resistance and a higher work function (approximately 7.5 eV) than those of the n-type GaN layer 33a. Accordingly, in order to form Ohmic contact between the p-type GaN layer 35a and the second electrode 42 and maintain transmittance of a designated level, the alloy layer 37 and the metal layer 38 are additionally formed on the p-type GaN layer 35a. The alloy layer 37 employed by the present invention is made of one alloy selected from the group consisting of Mn-based hydrogen-storing alloys, La-based hydrogen-storing alloys, Ni-based hydrogen-storing alloys and Mg-based hydrogen-storing alloys. MnNiFe or MnNi is used as the Mn-based hydrogen-storing alloy, LaNi₅ is used as the La-based hydrogen-storing alloy, ZnNi or MgNi is used as the Ni-based hydrogen-storing alloy, and ZnMg is used as the Mg-based hydrogen-storing alloy.

Generally, the hydrogen-storing alloy represents an alloy, which is chemically reacted with hydrogen and allows a surface of a metal to absorb hydrogen, and is thus referred to as a “hydrogen absorption storage alloy”. When a temperature falls or a pressure rises, the hydrogen absorption storage alloy absorbs hydrogen, thus being changed into a metal hydride and emitting heat simultaneously. On the other hand, when a temperature rises or a pressure falls, such a metal hydride discharges hydrogen and absorbs heat.

The alloy layer 37 is made of the hydrogen absorption storage alloy, which is one alloy selected from the group consisting of Mn-based hydrogen absorption storage alloys, La-based hydrogen absorption storage alloys, Ni-based hydrogen absorption storage alloys and Mg-based hydrogen absorption storage alloys. The alloy layer 37 absorbs hydrogen ions existing on the surface of the p-type GaN layer 35a based on characteristics of the hydrogen absorption storage alloy, thus preventing the hydrogen ions from being bonded to Mg serving as a dopant of the p-GaN layer 35a.

The p-type GaN layer 35a is low-density doped with Mg. Particularly, since Mg is reacted with hydrogen ions existing on the surface of the p-type GaN layer 35a, the density of Mg in the p-type GaN layer 35a is further reduced. Thereby, the p-type GaN layer 35a has an increased Ohmic resistance. When the alloy layer 37 having a thickness of approximately 10 Å to 100 Å is formed on the upper surface of the p-type GaN layer 35a by depositing the hydrogen-storing alloy i.e., the Mn-based hydrogen-storing alloy such as MnNiFe or MnNi, the La-based hydrogen-storing alloy such as LaNi₅, the Ni-based hydrogen-storing alloy such as ZnNi or MgNi, or the Mg-based hydrogen-storing alloy such as ZnMg, and is then thermally treated, the hydrogen-storing alloy absorbs hydrogen existing on the surface of the p-type GaN layer 35a, thus preventing hydrogen from being reacted with Mg serving as the dopant of the p-type GaN layer 35a, thereby activating Mg on the surface of the p-type GaN layer 35a and reducing the Ohmic resistance. The alloy layer 37 has a low transmittance. In order to prevent an overall transmittance of the light emitting diode from being lowered, the alloy layer 37 preferably has a thickness of approximately 100 Å or less, and more preferably has a thickness of approximately 50 Å. Most preferably, in order to absorb a sufficient amount of hydrogen ions, the alloy layer 37 has a thickness of approximately 10 Å or more.

In the GaN-based semiconductor light emitting diode of the present invention, the metal layer 38 is formed on the alloy layer 37 made of the hydrogen-storing alloy. The metal layer 38 is classified into two types according to packaging methods of the semiconductor light emitting diode. First, in case that the semiconductor light emitting diode is packaged by a wire-bonding method, a first metal layer made of one metal selected from the group consisting of Au, Pt, Ir and Ta is formed on the alloy layer 37. Second, in case that the semiconductor light emitting diode is packaged by a flip chip-bonding method, a second metal layer made of one metal selected from the group consisting of Rh, Al and Ag is formed on the alloy layer 37. In FIG. 2, the first and second metal layers are all denoted by reference numeral 38.

The first metal layer 38 improves Ohmic contact and current dispersal, and is made of one metal selected from the group consisting of Au, Pt, Ir and Ta, which is formed on the alloy layer 37. In order to prevent the deterioration of transmittance, the alloy layer 37 preferably has a thickness of approximately 100 Å or less, and more preferably has a thickness of approximately 50 Å. Further, preferably, the thickness of the first metal layer 38 is substantially the same as or larger than that of the alloy layer 37. The thickness of the first metal layer 38 and the thickness of the alloy layer 37 will be described in detail further.

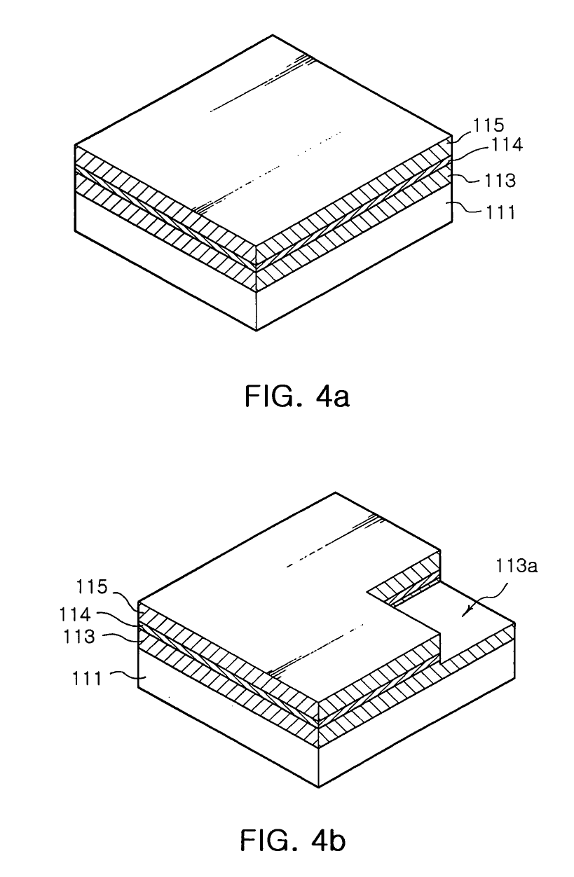

On the other hand, in case that the semiconductor light emitting diode is mounted on a circuit board or a lead frame by a flip chip-bonding method, the second metal layer 38 made of one metal selected from the group consisting of Rh, Al and Ag is formed on the alloy layer 37. FIG. 3 is a cross-sectional view of a flip chip bonding-type package of the GaN-based semiconductor light emitting diode in accordance with one embodiment of the present invention. As shown in FIG. 3, a GaN-based semiconductor light emitting diode 40′ is mounted on a circuit board 51 by directly connecting electrodes 41 and 42 to bumps 53 formed on metal patterns 52 formed on the upper surface of the circuit board 51, and light generated by the active layer 34 is reflected by the second metal layer 38 serving as a reflective layer and is then emitted toward the sapphire substrate 31. In case that the GaN-based semiconductor light emitting diode 41′ is packaged by a clip chip-bonding method as described above, generated blue light is emitted toward the sapphire substrate 31 and the second metal layer 38 made of one metal selected from the group consisting of Rh, Al and Ag serves as the reflective layer. Here, in order to allow the metal layer 38 to reflect a sufficient amount of light, the metal layer 38 preferably has a thickness of approximately 500 Å to 10,000 Å larger than that of the above-described first metal layer. Hereinafter, the metal layer 38 includes the first and second metal layers.

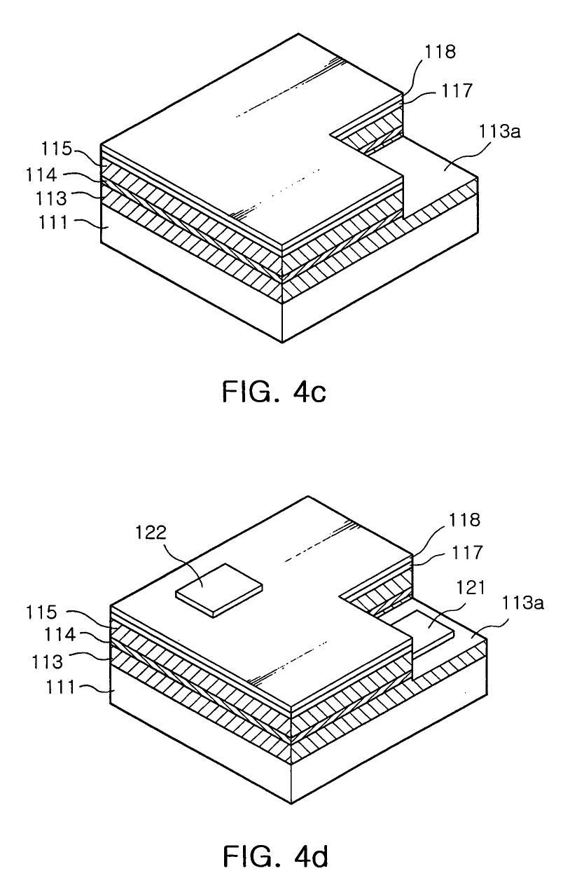

FIGS. 4a to 4d are perspective views illustrating a process for manufacturing a GaN-based semiconductor light emitting diode in accordance with the present invention.

First, as shown in FIG. 4a, a substrate 111 on which a GaN-based semiconductor material is grown is formed, and a lower clad layer 113 made of a first conductive semiconductor material, an active layer 114 and an upper clad layer 115 made of a second conductive semiconductor material are sequentially grown on the substrate 111. The substrate 111 is a sapphire substrate. Each of the lower clad layer 113 and the upper clad layer 115 includes a GaN layer and an AlGaN layer formed by the MOCVD method, as shown in FIG. 2.

Thereafter, as shown in FIG. 4b, designated portions of the upper clad layer 115 and the active layer 114 are removed so that a portion 113a of the lower clad layer 113 is exposed. The exposed portion 113a of the lower clad layer 113 serves as an area for forming an electrode thereon. The exposed portion 113a obtained by the removal of the designated portions of the upper clad layer 115 and the active layer 114 is varied according to positions of the electrode to be formed, and the electrode to be formed has various shapes and sizes. For example, the removed portions of the upper clad layer 115 and the active layer 114 contact one edge, or the electrode to be formed is extended along sides in order to disperse current density.

Thereafter, as shown in FIG. 4c, an alloy layer 117 and a metal layer 118 are sequentially formed on the upper clad layer 115. In the present invention, the alloy layer 117 is made of one metal selected from the group consisting of Mn-based hydrogen-storing alloys, La-based hydrogen-storing alloys, Ni-based hydrogen-storing alloys and Mg-based hydrogen-storing alloys in order to form Ohmic contact. As described above, MnNiFe or MnNi is used as the Mn-based hydrogen-storing alloy, LaNi₅ is used as the La-based hydrogen-storing alloy, ZnNi or MgNi is used as the Ni-based hydrogen-storing alloy, and ZnMg is used as the Mg-based hydrogen-storing alloy. Further, the metal layer 118 is made of one metal selected from the group consisting of Au, Pt, Ir, Ta, Rh, Al and Ag. Preferably, the alloy layer 117 and the metal layer 118 are formed by a physical vapor evaporation method in order to prevent the increase of a contact resistance due to hydrogen ions. In order to remove hydrogen ions existing on the surface of the upper clad layer 115, the upper clad layer 115 preferably undergoes UV treatment, plasma treatment or thermal treatment prior to the formation of the alloy layer 117 thereon.

Here, the alloy layer 117 and the metal layer 118 have a meshed structure. In case that the alloy layer 117 and the metal layer 118 have the meshed structure, as shown in FIG. 4b, a photo resist, which is arranged on the upper clad layer 115, is patterned so that the photo resist has another meshed structure opposite to desired meshed structures of the alloy layer 117 and the metal layer 118, and then the alloy layer 117 and the metal layer 118 are sequentially deposited on the upper clad layer 115. Thereafter, the meshed structures of the alloy layer 117 and the metal layer 118 are obtained by lifting off the photo resist. As described above, the meshed structures of the alloy layer 117 and the metal layer 118 do not limit the GaN-based semiconductor light emitting diode of the present invention.

Finally, as shown in FIG. 4d, a first electrode 121 is formed on the exposed portion 113a of the lower clad layer 113, and a second electrode 122 is formed on the metal layer 118. Prior to the formation of the first and second electrodes 121 and 122, as shown in FIG. 4d, it is possible to perform an additional step of thermally treating the alloy layer 117 and the metal layer 118 for improving properties such as Ohmic contact and transmittance. Preferably, the thermal treatment of the alloy layer 117 and the metal layer 118 is performed at a temperature of approximately 200° C. or more for 30 seconds or more in an air atmosphere.

As described above, the alloy layer 37 preferably has a thickness of approximately 10 Å or more in order to easily absorb hydrogen, and has a thickness of approximately 100 Å or less in order to prevent the deterioration of transmittance. Preferably, the first metal layer made of one metal selected from the group consisting of Au, Pt, Ir and Ta has a thickness of approximately 100 Å or less in order to prevent the deterioration of transmittance. Here, more preferably, the thickness of the first metal layer is substantially the same as or larger than the thickness of the alloy layer 117. Further, preferably, the second metal layer made of one metal selected from the group consisting of Rh, Al and Ag, serving as the reflective layer, has a thickness of approximately 500 Å to 10,000 Å.

In order to describe characteristics of the alloy layer 117 and the first metal layer 118 according to variation in thickness, Table 1 shows resulting characteristics of Ohmic contact and transmittance according to variation in the ratio of the thickness of the alloy layer 117 to the thickness of the first metal layer 118, and variation in the temperature of thermal treatment. Here, the alloy layer 117 was made of LaNi₅, and the first metal layer 118 was made of Au.

TABLE 1

| Thickness | Temp. of thermal | Driving voltage | Luminance |
|---|---|---|---|
| (Å) | treatment (° C.) | (V) | (mcd) |
| 50/80 | 450 | 2.87 | 7.19 |
| | 500 | 2.87 | 6.68 |
| | 550 | 2.87 | 9 |
| 50/50 | 450 | 2.88 | 9.79 |
| | 500 | 2.88 | 9.11 |
| | 550 | 2.88 | 9.39 |
| 50/25 | 450 | 3.58 | 4.33 |
| | 500 | 3.61 | 3.27 |
| | 550 | 3.88 | 3.77 |

With reference to Table 1, in case that the thickness of the alloy layer 117 is larger than the thickness of the first metal layer 118, the GaN-based semiconductor light emitting diode has a remarkably high driving voltage and a remarkably low luminance. In this case, the temperature of thermal treatment is insufficient for forming Ohmic contact and insufficient oxidation is achieved, thus decreasing transmittance. In case that the thickness of the first metal layer 118 is larger than the thickness of the alloy layer 117, the GaN-based semiconductor light emitting diode has the same driving voltage but a low luminance. In this case, the first metal layer 118 has a comparatively large thickness of 80 Å, thus decreasing transmittance. In case that the alloy layer 117 and the first metal layer 118 have the same thickness of 50 Å, the GaN-based semiconductor light emitting diode has good driving voltage and luminance. That is, in case that the ratio of the thickness of the alloy layer 117 and the thickness of the first metal layer 118 is 1:1, the GaN-based semiconductor light emitting diode has the optimum driving voltage and luminance. Accordingly, the first metal layer 118 preferably has a thickness substantially the same as or larger than that of the alloy layer 117. Most preferably, the ratio of the thickness of the alloy layer 117 to the thickness of the first metal layer 118 is 1:1.

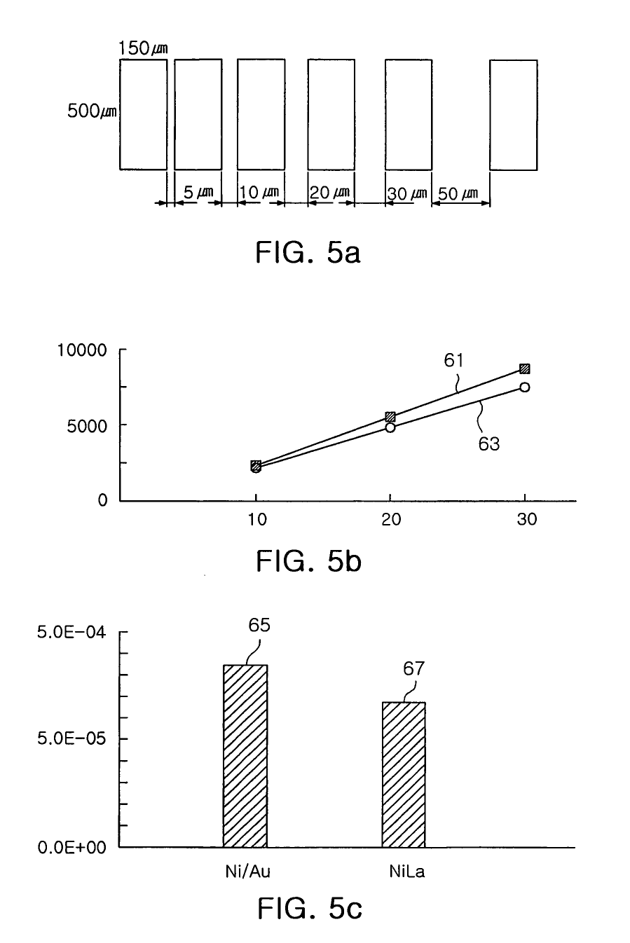

FIGS. 5a to 5c are graphs comparatively illustrating specific contact resistance of a Ni/Au layer of the conventional GaN-based semiconductor light emitting diode and specific contact resistance of an alloy layer/metal layer (particularly, LaNi₅/Au) of the GaN-based semiconductor light emitting diode of the present invention. FIG. 5a is a graph illustrating TLM (Transmission Length Mode) patterns of the Ni/Au layer of the conventional GaN-based semiconductor light emitting diode and the alloy layer/metal layer of the GaN-based semiconductor light emitting diode of the present invention, used for measuring the specific contact resistance. Here, a resistance between the respective patterns was measured, and obtained results are shown in FIG. 5b.

FIG. 5b is a graph illustrating resistances of the Ni/Au layer of the conventional GaN-based semiconductor light emitting diode and the alloy layer/metal layer of the GaN-based semiconductor light emitting diode of the present invention, in a section of 10 μm to 30 μm, in which linearity is excellent, based on the obtained results using the TLM patterns as shown in FIG. 5a. As shown in FIG. 5b, the resistance 63 of the alloy layer/metal layer of the GaN-based semiconductor light emitting diode of the present invention is lower than the resistance 61 of the Ni/Au layer of the conventional GaN-based semiconductor light emitting diode. FIG. 5c is a graph illustrating specific contact resistances of the Ni/Au layer of the conventional GaN-based semiconductor light emitting diode and the alloy layer/metal layer of the GaN-based semiconductor light emitting diode of the present invention, calculated by the resistances of FIG. 5b.

With reference to FIG. 5c, the specific contact resistance 67 of the alloy layer/metal layer of the GaN-based semiconductor light emitting diode of the present invention is approximately 5.7×10⁻⁵ Ω, which is lower that the specific contact resistance 65, i.e., approximately 7.4×10⁻⁵ Ω, of the Ni/Au layer of the conventional GaN-based semiconductor light emitting diode. Since the alloy layer/metal layer of the GaN-based semiconductor light emitting diode of the present invention has the specific contact resistance lower than that of the Ni/Au layer of the conventional GaN-based semiconductor light emitting diode, Ohmic contact of a higher quality is formed, thus improving a current injection property and decreasing a driving voltage.

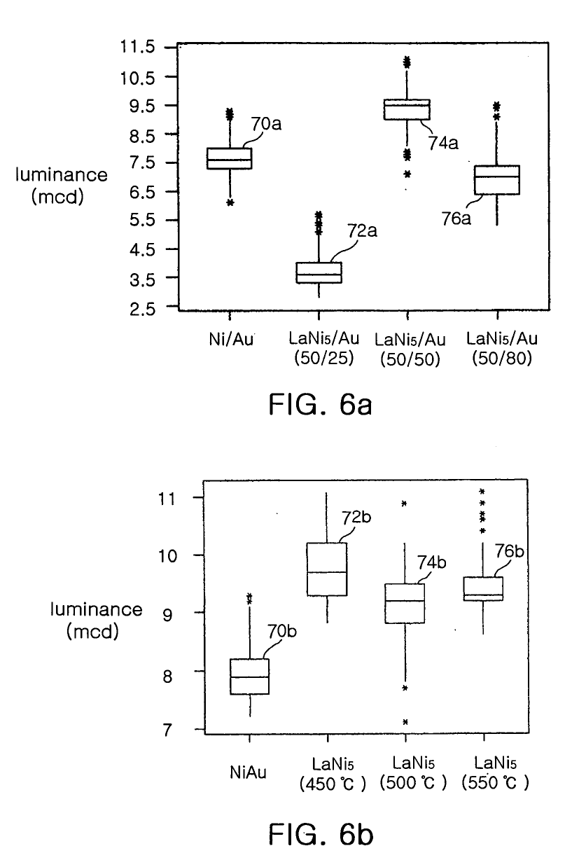

FIGS. 6a and 6b are graphs comparatively illustrating luminance of the conventional GaN-based semiconductor light emitting diode comprising the Ni/Au layer and luminance of the GaN-based semiconductor light emitting diode comprising the alloy layer/metal layer in accordance with the present invention. Here, the alloy layer was made of LaNi₅, and the first metal layer was made of Au. FIG. 6a is a graph comparatively illustrating luminance of the Ni/Au layer of the conventional GaN-based semiconductor light emitting diode and luminance of the alloy layer/metal layer of the GaN-based semiconductor light emitting diode of the present invention, at the same temperature of 500° C. in thermal treatment, according to variation in the thickness of the alloy layer/metal layer. As shown in FIG. 6a, in case that the alloy layer has a thickness of 50 Å and the metal layer has a thickness of 25 Å, the GaN-based semiconductor light emitting diode of the present invention has a luminance 72a slightly lower than the luminance 70a of the conventional GaN-based semiconductor light emitting diode comprising the Ni/Au layer. Further, in case that the alloy layer has a thickness of 50 Å and the metal layer has a thickness of 80 Å, the GaN-based semiconductor light emitting diode of the present invention has a luminance 76a similar to the luminance 70a of the conventional GaN-based semiconductor light emitting diode comprising the Ni/Au layer. In case that the alloy layer has a thickness of 50 Å and the metal layer has a thickness of 50 Å, the GaN-based semiconductor light emitting diode of the present invention has a luminance 74a much higher than the luminance 70a of the conventional GaN-based semiconductor light emitting diode comprising the Ni/Au layer. Accordingly, most preferably, the GaN-based semiconductor light emitting diode of the present invention comprises the alloy layer having a thickness of 50 Å and the metal layer having a thickness of 50 Å.

FIG. 6b is a graph comparatively illustrating luminance of the conventional GaN-based semiconductor light emitting diode comprising the Ni/Au layer and luminance of the GaN-based semiconductor light emitting diode comprising the alloy layer/metal layer in accordance with the present invention, under the condition that the metal layer has a thickness of 50 Å and the metal layer has a thickness of 50 Å, according to variation in the temperature in thermal treatment. In case that the alloy layers/the metal layers of the GaN-based semiconductor light emitting diode of the present invention, which are respectively thermally treated by temperatures of 450° C., 500° C. and 550° C., the GaN-based semiconductor light emitting diode of the present invention has respective luminances 72b, 74b and 76b much higher than the luminance 70b of the conventional GaN-based semiconductor light emitting diode comprising the Ni/Au layer. Thus, in accordance with the present invention, it is possible to manufacture a GaN-based semiconductor light emitting diode having a luminance higher than that of the conventional GaN-based semiconductor light emitting diode.

As apparent from the above description, the present invention provides a GaN-based semiconductor light emitting diode having a luminance higher than that of a conventional GaN-based semiconductor light emitting diode comprising a Ni/Au layer, and a method for manufacturing the GaN-based semiconductor light emitting diode. An alloy layer made of one alloy, i.e., a hydrogen-storing alloy, selected from the group consisting of Mn-based alloys, La-based alloys, Ni-based alloys and Mg-based alloys, is formed on a p-type GaN layer, thus preventing hydrogen from being reacted with a dopant, i.e., Mg, of the p-type GaN layer. Thereby, Mg serving as the dopant of the p-type GaN layer is activated, thus reducing Ohmic resistance and forming high-quality Ohmic contact.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A GaN-based semiconductor light emitting diode comprising:
a substrate on which a GaN-based semiconductor material is grown;
a lower clad layer formed on the substrate, and made of a first conductive GaN semiconductor material;
an active layer formed on a designated portion of the lower clad layer, and made of an undoped GaN semiconductor material;
an upper clad layer formed on the active layer, and made of a second conductive GaN semiconductor material; and
an alloy layer formed on the upper clad layer, and made of a hydrogen-storing alloy.

2. The GaN-based semiconductor light emitting diode as set forth in claim 1,
wherein the alloy layer is made of one hydrogen-storing alloy selected from the group consisting of Mn-based hydrogen-storing alloys, La-based hydrogen-storing alloys, Ni-based hydrogen-storing alloys and Mg-based hydrogen-storing alloys.

3. The GaN-based semiconductor light emitting diode as set forth in claim 2,
wherein the Mn-based hydrogen-storing alloy is MnNiFe or MnNi.

4. The GaN-based semiconductor light emitting diode as set forth in claim 2,
wherein the La-based hydrogen-storing alloy is LaNi₅.

5. The GaN-based semiconductor light emitting diode as set forth in claim 2,
wherein the Ni-based hydrogen-storing alloy is ZnNi or MgNi.

6. The GaN-based semiconductor light emitting diode as set forth in claim 2,
wherein the Mg-based hydrogen-storing alloy is ZnMg.

7. The GaN-based semiconductor light emitting diode as set forth in claim 1,
wherein the alloy layer has a thickness of 10 Å to 100 Å.

8. The GaN-based semiconductor light emitting diode as set forth in claim 1, further comprising:
a first metal layer formed on the alloy layer, and made of one metal selected from the group consisting of Au, Pt, Ir and Ta.

9. The GaN-based semiconductor light emitting diode as set forth in claim 8,
wherein the first metal layer has a thickness of 100 Å or less.

10. The GaN-based semiconductor light emitting diode as set forth in claim 8,
wherein the first metal layer has a thickness the same as or larger than that of the alloy layer.

11. The GaN-based semiconductor light emitting diode as set forth in claim 1, further comprising:
a second metal layer formed on the alloy layer, and made of one metal selected from the group consisting of Rh, Al and Ag.

12. The GaN-based semiconductor light emitting diode as set forth in claim 11,
wherein the second metal layer has a thickness of 500 Å to 10,000 Å.

13. A method for manufacturing a GaN-based semiconductor light emitting diode comprising the steps of:
(a) preparing a substrate on which a GaN-based semiconductor material is grown;
(b) forming a lower clad layer, made of a first conductive GaN semiconductor material, on the substrate;
(c) forming an active layer, made of an undoped GaN semiconductor material, on the lower clad layer;
(d) forming an upper clad layer, made of a second conductive GaN semiconductor material, on the active layer;
(e) removing designated portions of the upper clad layer and the active layer so as to expose a portion of the lower clad layer; and
(f) forming an alloy layer made of a hydrogen-storing alloy on the upper clad layer.

14. The method as set forth in claim 13,
wherein the step (f) is a step of forming the alloy layer made of one hydrogen-storing alloy selected from the group consisting of Mn-based hydrogen-storing alloys, La-based hydrogen-storing alloys, Ni-based hydrogen-storing alloys and Mg-based hydrogen-storing alloys.

15. The method as set forth in claim 14,
wherein the Mn-based hydrogen-storing alloy is MnNiFe or MnNi.

16. The method as set forth in claim 14,
wherein the La-based hydrogen-storing alloy is LaNi₅.

17. The method as set forth in claim 14,
wherein the Ni-based hydrogen-storing alloy is ZnNi or MgNi.

18. The method as set forth in claim 14,
wherein the Mg-based hydrogen-storing alloy is ZnMg.

19. The method as set forth in claim 13,
wherein the step (f) is a step of forming the alloy layer having a thickness of 10 Å to 100 Å.

20. The method as set forth in claim 13,
wherein the step (f) is a step of growing the alloy layer on the upper clad layer by physical vapor evaporation method.

21. The method as set forth in claim 13, further comprising the step of:
(g) allowing the surface of the upper clad layer to undergo UV treatment, plasma treatment or thermal treatment at a temperature of 400° C. or less.

22. The method as set forth in claim 13, further comprising the step of:
(h) forming a first metal layer, made of one metal selected from the group consisting of Au, Pt, Ir and Ta, on the alloy layer.

23. The method as set forth in claim 22,
wherein the step (h) is a step of forming the first metal layer having a thickness of 100 Å or less on the alloy layer.

24. The method as set forth in claim 22,
wherein the step (h) is a step of growing the first metal layer on the alloy layer by physical vapor evaporation method.

25. The method as set forth in claim 22,
wherein the step (h) is a step of forming the first metal layer having a thickness the same as or larger than that of the alloy layer.

26. The method as set forth in claim 22, further comprising the step of:
(i) thermally treating the alloy layer and the first metal layer.

27. The method as set forth in claim 26,
wherein the step (i) is a step of thermally treating the alloy layer and the first metal layer at a temperature of 200° C. or more for 10 seconds or more.

28. The method as set forth in claim 13, further comprising the step of:
(h′) forming a second metal layer, made of one metal selected from the group consisting of Rh, Al and Ag, on the alloy layer.

29. The method as set forth in claim 28,
wherein the step (h′) is a step of forming the second metal layer having a thickness of 500 Å to 10,000 Å on the alloy layer.

30. The method as set forth in claim 28,
wherein the step (h′) is a step of growing the second metal layer on the alloy layer by physical vapor evaporation method.

31. The method as set forth in claim 28, further comprising the step of:
(i′) thermally treating the alloy layer and the second metal layer.

32. The method as set forth in claim 31,
wherein the step (i′) is a step of thermally treating the alloy layer and the second metal layer at a temperature of 200° C. or more for 10 seconds or more.
